(19) United States
(12) Patent Application Publication
(10) Pub. No.: US 2025/0204219 A1
(43) Pub. Date: Jun. 19, 2025

(54) COVER WINDOW AND DISPLAY DEVICE INCLUDING THE SAME

(71) Applicant: Samsung Display Co., Ltd., Yongin-Si (KR)

(72) Inventor: Jong Hwan CHO, Yongin-si (KR)

(21) Appl. No.: 18/823,683

(22) Filed: Sep. 4, 2024

(30) Foreign Application Priority Data
Dec. 13, 2023 (KR) 10-2023-0181039

(51) Int. Cl. H10K 59/80

(52) U.S. Cl. CPC H10K 59/873; H10K 59/8792

(57) ABSTRACT

According to an embodiment of the disclosure, a cover window may include a window layer, a first refractive layer disposed on one surface of the window layer, a second refractive layer disposed on the first refractive layer, a cover layer disposed on the second refractive layer, an adhesive layer disposed between the cover layer and the second refractive layer, and a light blocking layer disposed on another surface of the window layer, and the first refractive layer may have a refractive index of 1.7 to 1.9.

This application claims priority to Korean Patent Application No. 10-2023-0181039 filed on Dec. 13, 2023, and all the benefits accruing therefrom under 35 U.S.C. § 119, the content of which in its entirety is herein incorporated by reference.

### BACKGROUND

### 1. Field

The disclosure relates to a cover window and a display device including the same.

### 2. Description of the Related Art

As information technology develops, importance of a display device, which is a connection medium between a user and information, is emerging. Accordingly, research and development on the display device is continuously being conducted.

The display device may include a display panel and a cover window disposed in front of the display panel. It may be desirable for the cover window to properly absorb external shock to protect the display panel and the like. In addition, it may be desirable for the cover window to have a low reflectance so as to increase a color reproduction rate by reducing interface reflection of the display device.

### SUMMARY

An aspect of the disclosure is to provide a cover window and a display device including the same capable of reducing a reflectance while increasing wear resistance by properly absorbing external shock.

According to an embodiment of the disclosure, a cover window may include a window layer, a first refractive layer disposed on one surface of the window layer, a second refractive layer disposed on the first refractive layer, a cover layer disposed on the second refractive layer, an adhesive layer disposed between the cover layer and the second refractive layer, and a light blocking layer disposed on another surface of the window layer, and the first refractive layer may have a refractive index of 1.7 to 1.9.

According to an embodiment, the first refractive layer may include stishovite, and the stishovite may be a nano polycrystal.

According to an embodiment, the first refractive layer may have a thickness of 5 nm to 50 nm.

According to an embodiment, the first refractive layer may be formed using a vapor deposition method of one or more of physical vapor deposition (PVD), electron beam (EB) deposition, ion assisted deposition-electron beam (IAD-EB), laser ablation, vacuum arc deposition, thermal evaporation, and plasma enhanced chemical vapor deposition (PECVD), and the second refractive layer, the adhesive layer, and the cover layer may be formed at a temperature of 120° C. to 350° C. using the EB.

According to an embodiment, the cover window may have a reflectance measured in a specular component included (SCI) mode of 0.2% to 0.5%.

According to an embodiment, the second refractive layer may include magnesium fluoride (MgF₂) or a solid solution mixed with magnesium fluoride (MgF₂), magnesium oxide (MgO), and yttrium oxyfluoride (YOF).

According to an embodiment, the second refractive layer may have a thickness of 50 nm to 150 nm.

According to an embodiment, the adhesive layer may include Si₉Al₂O₁₀.

According to an embodiment, the adhesive layer may have a thickness of 5 nm to 30 nm.

According to an embodiment, the cover layer may include perfluorinated polyether (PFPE).

According to an embodiment, the cover layer may have a thickness of 2 nm to 40 nm.

According to an embodiment, the light blocking layer may have a single-layer or multi-layer structure, and may include one or more of acryl urethane, epoxy, polyester, and epoxy ester.

According to an embodiment, the light blocking layer may include a first layer, and a second layer disposed on one surface of the first layer, the first layer may include acryl urethane or polyester and may have a thickness of 3 μm to 8 μm, and the second layer may include epoxy and may have a thickness of 5 μm to 10 μm.

According to an embodiment, the light blocking layer may include a first layer, and a second layer disposed on one surface of the first layer, the first layer may include polyester and may have a thickness of 3 μm to 8 μm, and the second layer may include epoxy ester and may have a thickness of 5 μm to 10 μm.

According to an embodiment, the light blocking layer may include a first layer, a second layer disposed on one surface of the first layer, and a third layer disposed on one surface of the second layer, the first layer and the second layer may include polyester, the third layer may include epoxy ester, the first layer may have a thickness of 2 μm to 5 μm, the second layer may have a thickness of 3 μm to 5 μm, and the third layer may have a thickness of 3 μm to 5 μm.

According to an embodiment, when measuring a color difference of the cover window using X-rite Ci 7800 equipment after 30 minutes of heat-resistant water in a constant temperature water bath having a temperature of 250° C. before deposition of the light blocking layer and a constant temperature water bath having a temperature of 80±2° C. after deposition of the light blocking layer, the cover window may have a color difference of 0.5 or less.

According to an embodiment of the disclosure, a cover window may include a window layer, a first refractive layer disposed on one surface of the window layer, a second refractive layer disposed on the first refractive layer, a cover layer disposed on the second refractive layer, an adhesive layer disposed between the cover layer and the second refractive layer, and a light blocking layer disposed on another surface of the window layer, and the first refractive layer may include stishovite.

According to an embodiment, the window layer, the first refractive layer, the second refractive layer, the adhesive layer, and the cover layer may have refractive indices of 1.52, 1.70 to 1.90, 1.38 to 1.40, 1.48, and 1.32, respectively, with respect to a wavelength of 550 nm.

According to an embodiment, the second refractive layer may include magnesium fluoride (MgF₂) or a solid solution mixed with magnesium fluoride (MgF₂), magnesium oxide (MgO), and yttrium oxyfluoride (YOF), the adhesive layer may include Si₉Al₂O₁₀, and the cover layer may include perfluorinated polyether (PFPE).

According to the disclosure, a display device may include a display panel overlapping the cover window.

According to an embodiment of the disclosure, a cover window and a display device including the same capable of reducing a reflectance while increasing wear resistance by properly absorbing external shock may be provided.

### BRIEF DESCRIPTION OF THE DRAWINGS

The above and other features of the disclosure will become more apparent by describing in further detailed description of embodiments thereof with reference to the accompanying drawings, in which:

FIG. 1 is a schematic cross-sectional view illustrating a cover window according to a first embodiment;

FIG. 2 is a schematic cross-sectional view illustrating a cover window according to a second embodiment;

FIG. 3 is a schematic cross-sectional view illustrating a cover window according to a third embodiment;

FIG. 4 is a table illustrating a grade according to a peeling area in a tape detachment test; and

FIG. 5 is a schematic cross-sectional view of a display device according to an embodiment.

### DETAILED DESCRIPTION OF THE EMBODIMENT

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and the other portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and the other portion.

The disclosure relates to a cover window and a display device including the same. Hereinafter, a cover window according to an embodiment and a display device including the same are described with reference to the attached drawings.

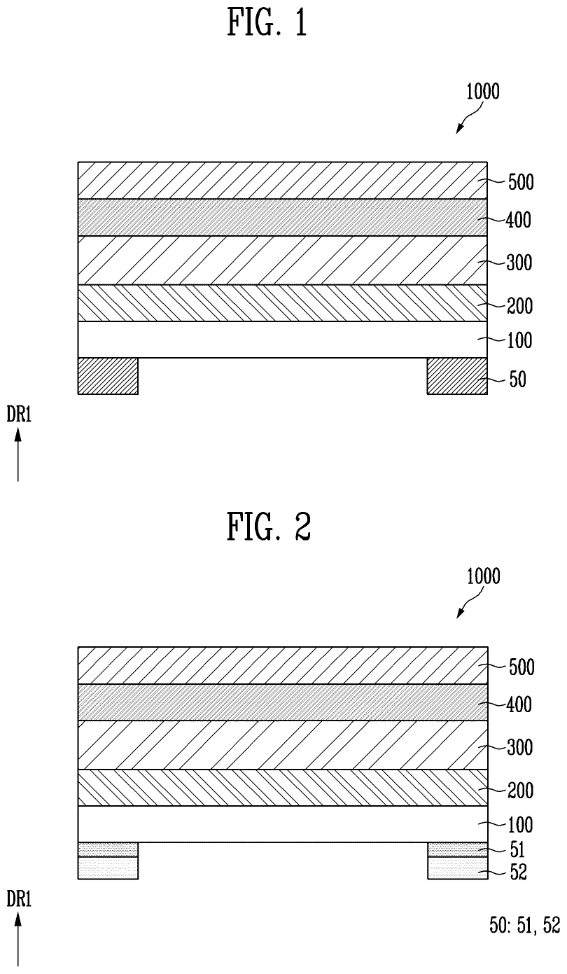

FIG. 1 is a schematic cross-sectional view illustrating a cover window according to a first embodiment.

Referring to FIG. 1, the cover window 1000 according to the disclosure includes may include a window layer 100, a light blocking layer 50 disposed on a surface (for example, a rear surface) of the window layer 100, a first refractive layer 200 disposed on another surface (for example, a front surface) of the window layer 100, a second refractive layer 300 disposed on the first refractive layer 200, an adhesive layer 400 disposed on the second refractive layer 300, and a cover layer 500 disposed on the adhesive layer 400.

The cover window 1000 according to the disclosure may have a reflectance of 0.2% to 0.5% and improved wear resistance. Each configuration is described below.

The window layer 100 may include glass or polymer. According to an embodiment, an example of the polymer may include polyimide, but is not limited thereto. According to an embodiment, the window layer 100 may include one or more of glass, plastic film, and ultra-thin chemically strengthened glass (UTG™).

According to an embodiment, the window layer 100 may have a refractive index of 1.52 with respect to light having a wavelength of 550 nm. However, the disclosure is not limited thereto.

The first refractive layer 200 may be positioned (or disposed) on one surface of the window layer 100. The first refractive layer 200 may contact one surface of the window layer 100. The first refractive layer 200 may reduce the reflectance of the cover window 1000 and improve the wear resistance of the cover window 1000.

The first refractive layer 200 may include stishovite. According to an embodiment, the first refractive layer 200 may include nano-polycrystalline shape of stishovite. For example, the first refractive layer 200 may include polycrystalline stishovite having a crystal size of nanometer (nm).

The first refractive layer 200 according to the disclosure may include nano-polycrystalline shape of stishovite, and may improve vibration wear resistance of the cover window 1000. When the cover window 1000 does not include the first refractive layer 200, in a case where an abrasive stone or the like is vibrated and rotated on a surface of the cover window 1000, a larger amount of scratches may occur on the surface of the cover window 1000 than a case where the cover window 1000 includes the first refractive layer 200. Experimentally, stishovite has relatively high hardness and high toughness (for example, fracture resistance) compared to other materials. Therefore, due to a material property of stishovite, the cover window 1000 according to the disclosure may improve vibration wear resistance.

The first refractive layer 200 may be formed using at least one vapor deposition method. For example, the vapor deposition method may include physical vapor deposition (PVD), electron beam (EB) deposition, ion assisted deposition-electron beam (IAD-EB), laser ablation, vacuum arc deposition, thermal evaporation, plasma enhanced chemical vapor deposition (PECVD), and the like.

According to an embodiment, the first refractive layer 200 may have a refractive index of 1.7 to 1.9 with respect to light having a wavelength of 550 nm. The first refractive layer 200 may be a high refractive index layer.

The first refractive layer 200 according to the disclosure may have a refractive index of 1.7 to 1.9, and the cover window 1000 may have a reflectance measured in a specular component included (SCI) mode of 0.2% to 0.5%.

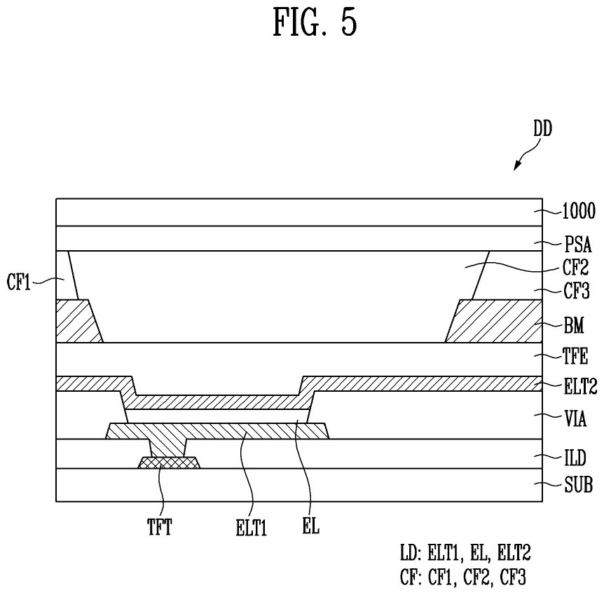

In a display device DD (refer to FIG. 5) including the cover window 1000, when a surface reflection is generated greatly, a reflectance of the display device DD may increase and display quality may be deteriorated. In a case of the display device DD, since most reflection occurs on a surface of the cover window 1000, reducing the reflectance of the cover window 1000 may be required. The cover window 1000 according to the disclosure may reduce the reflectance of the cover window 1000 to 0.2% to 0.5%.

According to an embodiment, a thickness of the first refractive layer 200 may be 5 nm to 50 nm. Hereinafter, in the disclosure, thickness is defined as a length along a first direction DR1. When the thickness of the first refractive layer 200 is less than 5 nm, a surface reflectance of the cover window 1000 may not be sufficiently reduced. When the thickness of the first refractive layer 200 is greater than 50 nm, durability of the cover window 1000 may be reduced.

The second refractive layer 300 may be positioned on the first refractive layer 200. The second refractive layer 300 may be in contact with the first refractive layer 200.

According to an embodiment, the second refractive layer 300 may include magnesium fluoride (MgF₂). According to an embodiment, the second refractive layer 300 may include a solid solution mixed with magnesium fluoride (MgF₂), magnesium oxide (MgO), and yttrium oxyfluoride (YOF).

According to an embodiment, the second refractive layer 300 may have a refractive index of 1.38 to 1.40 with respect to light having a wavelength of 550 nm. The second refractive layer 300 may be a low refractive index layer which has a refractive index lower than that of the first refractive layer 200. As the refractive index of the second refractive layer 300 satisfies the range described above with respect to the light having the wavelength of 550 nm, the surface reflectance of the cover window 1000 may be reduced.

According to an embodiment, a thickness of the second refractive layer 300 may be 50 nm to 150 nm. When the thickness of the second refractive layer 300 is less than 50 nm, the surface reflectance of the cover window 1000 may not be sufficiently reduced. When the thickness of the second refractive layer 300 is greater than 150 nm, mechanical strength of the cover window 1000 may be reduced, and thus durability may be reduced. Therefore a total thickness of the cover window 1000 may increase, and thus the entire thickness of the display device may be excessively increased.

According to an embodiment, the second refractive layer 300 may be formed through an ion-assisted deposition process. According to an embodiment, in a process of forming the second refractive layer 300, each of magnesium fluoride (MgF₂), magnesium oxide (MgO), and yttrium oxyfluoride (YOF) may be deposited in a particle form, an ionized argon (Ar) gas or oxygen (O₂) gas may be provided during a deposition process, and thus adhesion of a deposited film to a surface of the first refractive layer 200 may be improved. Alternatively, in the process of forming the second refractive layer 300, magnesium fluoride (MgF₂) may be formed as a single layer, magnesium fluoride (MgF₂) may be deposited in a particle form, an ionized argon (Ar) gas or oxygen (O₂) gas may be provided during a deposition process, and thus adhesion of a deposited film to a surface of the first refractive layer 200 may be improved.

The adhesive layer 400 may be disposed on the second refractive layer 300. The adhesive layer 400 may be in contact with the second refractive layer 300. The adhesive layer 400 may be disposed between the second refractive layer 300 and the cover layer 500 to increase adhesion between the second refractive layer 300 and the cover layer 500.

The adhesive layer 400 may include SiO₂ and Al₂O₃. According to an embodiment, the adhesive layer 400 may include a substitutional solid solution including SiO₂ and Al₂O₃. For example, each of SiO₂ and Al₂O₃ may not be included in the adhesive layer 400, and an element of SiO₂ and Al₂O₃ may be substituted each other in the adhesive layer 400 to form a crystal structure. According to an embodiment, the adhesive layer 400 may include Si₉Al₂O₁₀.

According to an embodiment, a refractive index of the adhesive layer 400 with respect to light having a wavelength of 550 nm may be 1.48. Therefore, the adhesive layer 400 may also contribute to reducing the reflectance of the cover window 1000.

A thickness of the adhesive layer 400 may be 5 nm to 30 nm. When the thickness of the adhesive layer 400 is less than 5 nm, adhesive performance may be reduced, and when the thickness of the adhesive layer 400 is greater than 30 nm, a transmittance may be reduced.

The cover layer 500 may be positioned on the adhesive layer 400. The cover layer 500 may be in contact with the adhesive layer 400. The cover layer 500 may be positioned on a surface of the cover window 1000 and may suppress wear of a surface.

According to an embodiment, the cover layer 500 may include perfluorinated polyether (PFPE). In the PFPE, a highly flexible ether bond is introduced into a hard and short perfluoroalkyl chain. Therefore, the cover layer 500 may have a soft amorphous property, an excellent anti-fingerprint property, and an excellent slip property.

According to an embodiment, a refractive index of the cover layer 500 at a wavelength of 550 nm may be 1.32. Therefore, the cover layer 500 may also contribute to reducing the reflectance of the cover window 1000.

A thickness of the cover layer 500 may be 2 nm to 40 nm. When the thickness of the cover layer 500 is less than 2 nm, the cover window 1000 may not have sufficient wear resistance performance. When the thickness of the cover layer 500 is greater than 40 nm, a transmittance of the cover window 1000 may be impaired.

The light blocking layer 50 may be positioned along an edge of the cover window 1000. The light blocking layer 50 may be positioned on another surface of the window layer 100. The light blocking layer 50 may be in contact with the window layer 100.

The light blocking layer 50 may prevent a line, a circuit, or the like positioned in a display panel from being identified from an outside and may prevent light leakage of the display panel. A portion where the light blocking layer 50 is disposed may be a bezel area of the display device DD.

FIG. 1 shows a configuration in which the light blocking layer 50 is a single layer, but the light blocking layer 50 may have a single-layer or multi-layer structure and may include one or more acryl urethane, epoxy, polyester, and epoxy ester.

According to an embodiment, a thickness of the light blocking layer 50 may be 5 μm to 20 μm. When the thickness of the light blocking layer 50 is 5 μm or less, a risk that light leakage may occur, and when the thickness of the light blocking layer 50 is greater than 20 μm, a step between an area where the light blocking layer 50 is formed and an area where the light blocking layer 50 is not formed may increase, and thus it is not desirable.

The light blocking layer 50 may have heat resistance capable of withstanding a deposition temperature for forming the second refractive layer 300, the adhesive layer 400, and the cover layer 500 on the window layer 100. According to an embodiment, the second refractive layer 300, the adhesive layer 400, and the cover layer 500 may be formed using the EB which has a process temperature between 120° C. and 350° C. According to an embodiment, the process temperature may be 150° C. Therefore, it may be appropriate for the light blocking layer 50 to have heat resistance without losing adhesion at a temperature of 120° C. to 350° C. According to the disclosure, the second refractive layer 300, the adhesive layer 400, and the cover layer 500 may be formed continuously in one chamber, and a process may be simplified.

FIG. 2 is a schematic cross-sectional view illustrating a cover window according to a second embodiment.

Hereinafter, the cover window 1000 according to the second embodiment is described with reference to FIG. 2. The second embodiment is the same as the embodiment of FIG. 1 except that the light blocking layer 50 includes a first layer 51 and a second layer 52. Hereinafter, a detailed description of the same component is omitted.

The light blocking layer 50 may include the first layer 51 and the second layer 52 disposed on one surface (for example, a lower surface) of the first layer 51. The first layer 51 may be in contact with the window layer 100. The second layer 52 may be in contact with the first layer 51 and may be disposed under the first layer 51. In the disclosure, an “under” may be defined as a gravity direction and may be an opposite direction of the first direction DR1.

According to an embodiment, the first layer 51 may include acryl urethane, and the second layer 220 may include epoxy. Alternatively, the first layer 210 may include polyester, and the second layer 220 may include epoxy. Alternatively, the first layer 210 may include polyester, and the second layer 220 may include epoxy ester.

In the second embodiment, a thickness of the first layer 210 may be 3 μm to 8 μm. A thickness of the second layer 220 may be 5 μm to 10 μm.

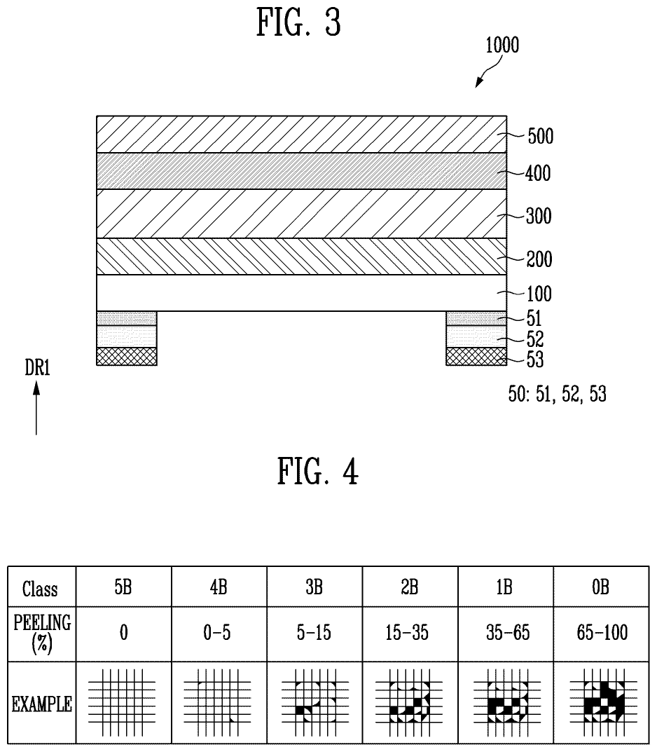

FIG. 3 is a schematic cross-sectional view illustrating a cover window according to a third embodiment.

Hereinafter, the cover window 1000 according to the third embodiment is described with reference to FIG. 3. The third embodiment is the same as the embodiment of FIG. 1 except that the light blocking layer 50 includes a first layer 51, a second layer 52, and a third layer 53. Hereinafter, a detailed description of the same component is omitted.

Referring to FIG. 3, the light blocking layer 50 may include a first layer 51, a second layer 52 disposed on one surface (for example, a lower surface) of the first layer 51, and a third layer 53 disposed on one surface (for example, a lower surface) of the second layer 52. The first layer 51 may be in contact with the window layer 100. The second layer 52 may be in contact with the first layer 51 and may be disposed under the first layer 51. The third layer 53 may be in contact with the second layer 52 and may be disposed under the second layer 52.

According to an embodiment, the first layer 51 and the second layer 52 may include polyester, and the third layer 53 may include epoxy ester.

In the third embodiment, a thickness of the first layer 51 may be 2 μm to 5 μm, a thickness of the second layer 52 may be 3 μm to 5 μm, and a thickness of the third layer 230 may be 3 μm to 5 μm.

Then, a physical property 1000 of the cover window according to the disclosure is described below with reference to an experimental result.

FIG. 4 is a table illustrating a grade according to a peeling area in a tape detachment test. As shown in FIG. 4, a peeling test of 4B to 5B has the peeling area less than or equal to 5% after the tape detachment test.

Table 1 below shows a result of measuring a physical property of the cover window 1000 according to the disclosure in the tape detachment test before/after deposition of the light blocking layer 50.

TABLE 1

| Adhesion (Print surface X-Cutting after | Color difference (Print surface ΔE after |
|---|---|
| heat-resistant water before/after deposition) | heat-resistant water before/after deposition) |
| All 4B or more | All less than or equal to 0.5 |

Referring to Table 1, a peeling degree of the cover window 1000 according to the disclosure is measured after heat-resistant water of 30 minutes in a constant temperature water bath having a temperature of 80±2° C. after deposition at 250° C. before deposition of the light blocking layer 50. It may be confirmed that the cover window 1000 has adhesion of 4B or more, that is, a peeling area after tape detachment test may be less than or equal to 5%, and thus the cover window 1000 has excellent adhesion.

In addition, a color difference ΔE of the cover window is measured after heat-resistant water of 30 minutes in a constant temperature water bath having a temperature of 80±2° C. after deposition at 250° C. before deposition. In measuring the color difference, X-rite Ci 7800 equipment is used. It may be confirmed that a measured value is less than or equal to 0.5 or and indicates that a color deviation is not perceptible in appearance.

Table 2 below shows a result of measuring various physical properties of the cover window 1000 according to the disclosure.

TABLE 2

| SCI | | | | | | | |
|---|---|---|---|---|---|---|---|
| Reflectance | SCE | | Eraser contact angle (10K) | | | Steel Wool | |
| (%) | a* | b* | Initial | 5K | 10K | 5K | 10K |
| All 0.2% | All greater than | All greater than | All 95° or higher | | | All 95° or | |
| to 0.5% | −2 and less than | −1.5 and less | | | | higher | |
| | 2 | than 0.5 | | | | | |

Referring to Table 2, all SCI reflectance of the cover window 1000 according to the disclosure are 0.2% to 0.5%. The SCI reflectance is a value obtained by measuring the cover window 1000 using X-rite Ci 7800 equipment.

Typically, in the display device DD including the cover window, a reflection occupancy rate by the cover window may be 77% and a reflection occupancy by the display panel may be 23%. When the display panel has a structure that does not include a polarizing layer (pol less), efficiency of the display panel may increase by 30% or more and color reproducibility may increase by 10%, or more but a reflectance may be increased. For example, a reflectance of a display panel that does not include a polarizing layer may increase by 1.2% compared to a display panel that includes a polarizing layer. Therefore, in a case of a cover window of a display device DD that does not include a polarization layer, it may be desirable that a reflectance is lower than that of a cover window of a display device DD that includes a polarization layer. Typically, since the reflectance of the cover window of the display device DD including the polarizing layer is 8%, the reflectance of the cover window of the display device DD which does not include a polarizing layer should be lower than 8% to be suitable for the display device DD.

In a case of the cover window 1000 according to the disclosure, it may be confirmed that the reflectance is 0.2% to 0.5% which is sufficiently low to be suitable for the display device DD, as confirmed in Table 2. Therefore, the cover window 1000 according to the present embodiment may be applied to the display device DD that does not include a polarization layer, thereby reducing a reflectance of the display device DD.

In addition, referring to Table 2, it may be confirmed that a* and b*, which represent color sense specular component excluded (SCE), are within a good level range. The color sense (SCE) is a value obtained by measured the cover window using X-rite Ci 7800 equipment as described above, it may be desirable that the color sense of the cover window satisfies “−2<a*<2 and −1.5<b*<0.5”. Referring to Table 2, it may be confirmed that the color sense (SCE) of the cover window 1000 according to the present embodiment satisfies the above-described range.

In addition, referring to Table 2, a wear resistance test using an eraser and steel wool is performed and a result thereof is shown. The wear resistance test is performed with a load of 1 Kg, 40 reciprocations/min, and a stroke of 15 mm, and a contact angle is measured after performing 5000 and 10000 times, respectively. A passing criteria is that the contact angle is 95° or higher after the number of evaluations and peeling of coating is not visible in appearance.

In a case of the wear resistance test using the eraser, the cover window 1000 according to the disclosure showed a contact angle of 95° or higher even after performing the wear resistance test 10000 times, it may be confirmed that the wear resistance is excellent. Similarly, in a case of the wear resistance test using steel wool, the cover window 1000 according to the disclosure showed a contact angle of more than 95° even after performing the wear resistance test 10000 times, it may be confirmed that the wear resistance is excellent.

That is, since the light blocking layer 50 of the cover window 1000 according to the disclosure has heat resistance at a temperature of 120° C. to 350° C., the cover window 1000 may be manufactured in one chamber, and thus a process may be economical. In addition, the first refractive layer 200 may be included in the cover window 1000, and thus durability (for example, wear resistance) of the cover window 1000 may be improved. In addition, since the adhesive layer 400 may include a substitutional solid solution of SiO₂ and Al₂O₃, adhesion to another layer may be improved, a mechanical property of the cover window 1000 may be improved, and the cover window 1000 may have an excellent wear resistance property.

In addition, since the cover window 1000 according to the disclosure has a reflectance of 0.2% to 0.5% as shown in Table 2, the cover window 1000 may be suitable for the display device DD, and the cover window 1000 may have excellent color sense and wear resistance property.

Then, a display device including a cover window according to the present embodiment is described below using FIG. 5 as an example. However, a structure of FIG. 5 is only an example, and the cover window 1000 may be positioned on a display panel of various structures and is not limited to the structure of FIG. 5. FIG. 5 is a schematic cross-sectional view of a display device according to an embodiment. Referring to FIG. 5, the display device DD may include a substrate SUB. The substrate SUB may include glass or polyimide.

A transistor TFT may be disposed on the substrate SUB. The transistor TFT may include a gate electrode, a semiconductor layer, a source electrode, and a drain electrode, and may be electrically connected to a first electrode ELT1.

An interlayer insulating layer ILD may be disposed on the transistor TFT. The interlayer insulating layer ILD may include an inorganic insulating material such as silicon nitride (SiNx), silicon oxide (SiOx), and silicon nitride (SiOxNy). Alternatively, the interlayer insulating layer ILD may be an organic layer. According to an embodiment, the interlayer insulating layer ILD may include an organic insulating material which includes a general-purpose polymer such as polymethylmethacrylate or polystyrene, a polymer derivative having a phenol-based group, an acryl-based polymer, an imide-based polymer, polyimide, and a siloxane-based polymer.

An insulating layer VIA may be disposed on the first electrode ELT1. The insulating layer VIA may be an organic layer. Specifically, the insulating layer VIA may include an organic insulating material which includes a general-purpose polymer such as polymethylmethacrylate or polystyrene, a polymer derivative having a phenol-based group, an acryl-based polymer, an imide-based polymer, polyimide, and a siloxane-based polymer.

The insulating layer VIA may include an opening that exposes the first electrode ELT1, and a light emitting layer EL may be positioned in the opening of the insulating layer VIA. A second electrode ELT2 may be positioned on the insulating layer VIA and the light emitting layer EL. The first electrode ELT1, the light emitting layer EL, and the second electrode ELT2 may constitute a light emitting element LD.

According to an embodiment, the first electrode ELT1 may be an anode electrode of the light emitting element LD, and the second electrode ELT2 may be a cathode electrode of the light emitting element LD. However, the disclosure is not limited thereto. According to an embodiment, the first electrode ELT1 may be a cathode electrode of the light emitting element LD, and the second electrode ELT2 may be an anode electrode of the light emitting element LD.

An encapsulation layer TFE may be positioned on the second electrode ELT2. The encapsulation layer TFE may have a structure in which an inorganic layer and an organic layer are alternately stacked, and may protect the light emitting element LD from external moisture, humidity, or the like.

A light blocking member BM may be positioned on the encapsulation layer TFE. The light blocking member BM may be positioned in an area that does not overlap the light emitting layer EL, and may be positioned to overlap a line (not shown) positioned on the substrate SUB to prevent light leakage.

A color filter CF may be positioned on the encapsulation layer TFE. The color filter CF may include a first color filter CF1, a second color filter CF2, and a third color filter CF3.

An adhesive layer PSA may be positioned on the color filter CF. The cover window 1000 may be attached through the adhesive layer PSA. A description of the cover window 1000 is the same as that described above, and thus the description of the cover window 1000 is omitted.

As shown in FIG. 5, the display device DD according to the present embodiment may not include a polarization layer therein. In this case, efficiency may increase by 30% or more and color reproducibility may increase by 10% or more, but a reflectance may also be increased. However, in the display device DD according to the disclosure, since the reflectance of the cover window 1000 is 0.2% to 0.5%, the reflectance of the display device DD which does not include a polarization layer may be maintained to a level similar to the reflectance of the display device including a polarization layer. Therefore, efficiency may be improved and color reproducibility may be improved without increasing a reflectance.

As described above, although the disclosure has been described with reference to the preferred embodiment above, those skilled in the art or those having a common knowledge in the art will understand that the disclosure may be variously modified and changed without departing from the spirit and technical area of the disclosure described in the claims which will be described later.

Therefore, the technical scope of the disclosure should not be limited to the contents described in the detailed description of the specification, but should be defined by the claims. cm What is claimed is:

1. A cover window comprising:
a window layer;
a first refractive layer disposed on one surface of the window layer;
a second refractive layer disposed on the first refractive layer;
a cover layer disposed on the second refractive layer;
an adhesive layer disposed between the cover layer and the second refractive layer; and
a light blocking layer disposed on another surface of the window layer,
wherein the first refractive layer has a refractive index of 1.7 to 1.9.

2. The cover window according to claim 1, wherein the first refractive layer includes stishovite, and
wherein the stishovite is a nano polycrystal.

3. The cover window according to claim 1, wherein the first refractive layer has a thickness of 5 nm to 50 nm.

4. The cover window according to claim 1, wherein the first refractive layer is formed using a vapor deposition method of one or more of physical vapor deposition (PVD), electron beam (EB) deposition, ion assisted deposition-electron beam (IAD-EB), laser ablation, vacuum arc deposition, thermal evaporation, and plasma enhanced chemical vapor deposition (PECVD), and
wherein the second refractive layer, the adhesive layer, and the cover layer are formed at a temperature of 120° C. to 350° C. using the EB.

5. The cover window according to claim 1, wherein the cover window has a reflectance measured in a specular component included (SCI) mode of 0.2% to 0.5%.

6. The cover window according to claim 1, wherein the second refractive layer includes magnesium fluoride (MgF₂) or a solid solution mixed with magnesium fluoride (MgF₂), magnesium oxide (MgO), and yttrium oxyfluoride (YOF).

7. The cover window according to claim 1, wherein the second refractive layer has a thickness of 50 nm to 150 nm.

8. The cover window according to claim 1, wherein the adhesive layer includes Si₉Al₂O₁₀.

9. The cover window according to claim 1, wherein the adhesive layer has a thickness of 5 nm to 30 nm.

10. The cover window according to claim 1, wherein the cover layer includes perfluorinated polyether (PFPE).

11. The cover window according to claim 1, wherein the cover layer has a thickness of 2 nm to 40 nm.

12. The cover window according to claim 1, wherein the light blocking layer has a single-layer or multi-layer structure, and includes one or more of acryl urethane, epoxy, polyester, and epoxy ester.

13. The cover window according to claim 1, wherein the light blocking layer comprises:
a first layer; and
a second layer disposed on one surface of the first layer,
wherein the first layer includes acryl urethane or polyester and has a thickness of 3 μm to 8 μm, and
wherein the second layer includes epoxy and has a thickness of 5 μm to 10 μm.

14. The cover window according to claim 1, wherein the light blocking layer comprises:
a first layer; and
a second layer disposed on one surface of the first layer,
wherein the first layer includes polyester and has a thickness of 3 μm to 8 μm, and
wherein the second layer includes epoxy ester and has a thickness of 5 μm to 10 μm.

15. The cover window according to claim 1, wherein the light blocking layer comprises:
a first layer;
a second layer disposed on one surface of the first layer; and
a third layer disposed on one surface of the second layer,
wherein the first layer and the second layer include polyester, the third layer includes epoxy ester, the first layer has a thickness of 2 μm to 5 μm, the second layer has a thickness of 3 μm to 5 μm, and the third layer has a thickness of 3 μm to 5 μm.

16. The cover window according to claim 1, wherein when measuring a color difference of the cover window using X-rite Ci 7800 equipment after 30 minutes of heat-resistant water in a constant temperature water bath having a temperature of 250° C. before deposition of the light blocking layer and a constant temperature water bath having a temperature of 80±2° C. after deposition of the light blocking layer, the cover window has a color difference of 0.5 or less.

17. A cover window comprising:
a window layer;
a first refractive layer disposed on one surface of the window layer;
a second refractive layer disposed on the first refractive layer;
a cover layer disposed on the second refractive layer;
an adhesive layer disposed between the cover layer and the second refractive layer; and
a light blocking layer disposed on another surface of the window layer,
wherein the first refractive layer includes stishovite.

18. The cover window according to claim 17, wherein the window layer, the first refractive layer, the second refractive layer, the adhesive layer, and the cover layer have refractive indices of 1.52, 1.7 to 1.9, 1.38 to 1.40, 1.48, and 1.32, respectively, with respect to light having a wavelength of 550 nm.

19. The cover window according to claim 17, wherein the second refractive layer includes magnesium fluoride (MgF₂) or a solid solution mixed with magnesium fluoride (MgF₂), magnesium oxide (MgO), and yttrium oxyfluoride (YOF),
wherein the adhesive layer includes Si₉Al₂O₁₀, and
wherein the cover layer includes perfluorinated polyether (PFPE).

20. A display device comprising:
a window layer;
a first refractive layer disposed on one surface of the window layer;
a second refractive layer disposed on the first refractive layer;
a cover layer disposed on the second refractive layer;
an adhesive layer disposed between the cover layer and the second refractive layer;
a light blocking layer disposed on another surface of the window layer; and
a display panel overlapping the cover window,
wherein the first refractive layer has a refractive index of 1.7 to 1.9.
